(19) United States
(12) Patent Application Publication
(10) Pub. No.: US 2017/0133545 A1
(43) Pub. Date: May 11, 2017

(54) PASSIVATED CONTACTS FOR PHOTOVOLTAIC CELLS

(71) Applicant: SolarWorld Americas Inc., Hillsboro, OR (US)

(72) Inventors: Nathan Stoddard, Beaverton, OR (US); Bjoern Seipel, Beaverton, OR (US)

(21) Appl. No.: 14/935,790

(22) Filed: Nov. 9, 2015

(51) Int. Cl. H01L 31/18; H01L 31/068; H01L 31/0236; H01L 31/0216; H01L 31/0224

(52) U.S. Cl. CPC H01L 31/1804; H01L 31/1872; H01L 31/02168; H01L 31/022425; H01L 31/02366; H01L 31/068; H01L 31/1868

(57) ABSTRACT

A method of fabricating a passivated contact for a photovoltaic cell includes depositing a tunneling oxide layer on a first face of a substrate. An amorphous silicon layer is then deposited on top of the tunneling oxide layer. An aluminum layer is screen printed on top of the amorphous silicon layer. The aluminum layer is configured to serve as a crystallization catalyst for the amorphous silicon layer. The amorphous silicon layer and the aluminum layer are then heated to a crystallization temperature that is configured to cause the amorphous silicon to crystallize and to sinter the aluminum layer.

### TECHNICAL FIELD

The present disclosure relates generally to photovoltaic cells, and, in particular, to methods of fabricating photovoltaic cells.

### BACKGROUND

Photovoltaic (PV) cells are typically photovoltaic devices that convert sunlight directly into electricity. PV cells commonly include a semiconductor (e.g., silicon) that absorbs light irradiation (e.g., sunlight) in a way that creates free electrons, which in turn are caused to flow in the presence of a built-in field to create direct current (DC) power. The DC power generated by several PV cells may be collected on a grid placed on the cell. Current from multiple PV cells is then combined by series and parallel combinations into higher currents and voltages. The DC power thus collected may then be sent over wires, often many dozens or even hundreds of wires.

One type of PV cell that is currently being developed is a passivated emitter and rear contact (PERC) PV cell. The efficiency of PERC cells is limited in part due to recombination at the metal contacts on the backface of the cell. The trade-off between passivation area (higher V_{oc}) and current conduction area (higher fill factor) also imposes limits. What is needed is a method of achieving passivated contacts in PV cells that is economical and easily produced.

### SUMMARY

In one embodiment, a method of fabricating a passivated contact for a photovoltaic cell comprises depositing a tunneling oxide layer on a first face of a substrate. An amorphous silicon layer is then deposited on top of the tunneling oxide layer. An aluminum layer is screen printed on top of the amorphous silicon layer. The aluminum layer is configured to serve as a crystallization catalyst for the amorphous silicon layer. The amorphous silicon layer and the aluminum layer are then heated to a crystallization temperature that is configured to cause the amorphous silicon to crystallize and to sinter the aluminum layer.

In another embodiment, a method of fabricating a passivated full-field back contact for a photovoltaic cell comprises depositing a tunneling oxide layer on a back face of a substrate, and depositing a doped amorphous silicon layer on top of the tunneling oxide layer. An aluminum layer is then screen printed on top of the amorphous silicon layer on a full field to form a full-field back contact that is configured to serve as a crystallization catalyst for the amorphous silicon layer. The amorphous silicon layer and the aluminum layer are then heated to a crystallization temperature that is configured to cause the amorphous silicon to crystallize and to sinter the aluminum layer to form a full-field back contact.

In yet another embodiment, a method of fabricating a passivated partial-field back contact for a photovoltaic cell comprises depositing a tunneling oxide layer on a back face of a substrate, and depositing a doped amorphous silicon layer on top of the tunneling oxide layer. An aluminum layer is then screen printed on top of the amorphous silicon layer on a partial field to form a partial-field back contact that is configured to serve as a crystallization catalyst for the amorphous silicon layer. The amorphous silicon layer and the aluminum layer are then heated to a crystallization temperature that is configured to cause the amorphous silicon to crystallize and to sinter the aluminum layer to form a partial-field back contact.

In another embodiment, a method of fabricating passivated front and back contacts for a photovoltaic cell comprises depositing a tunneling oxide layer on a back face of a substrate, and depositing a doped amorphous silicon layer on top of the tunneling oxide layer. An aluminum layer is screen printed on top of the amorphous silicon layer on the back face, and an aluminum-silver mix is screen printed on the front face. The amorphous silicon layer and the aluminum layer are then heated to a crystallization temperature that is configured to cause the amorphous silicon to crystallize and to sinter the aluminum layer on both the front and back faces.

### DRAWINGS

FIG. 1 is a flowchart of the steps utilized to generate a passivated contact on a face of a photovoltaic cell.

FIG. 2 is a schematic illustration of a first embodiment of a PERC PV cell having a full field passivated back face contact in accordance with the present disclosure.

FIG. 3 is a flowchart of a process for fabricating the PV cell of FIG. 2.

FIG. 4 is a schematic illustration of a second embodiment of a PERC PV cell having a full field passivated back face contact in accordance with the present disclosure.

FIG. 5 is a flowchart of a process for fabricating the PV cell of FIG. 4.

FIG. 6 is a schematic illustration of a third embodiment of a bifacial PERC PV cell having a partial field passivated back face contact in accordance with the present disclosure.

FIG. 7 is a flowchart of a process for fabricating the PV cell of FIG. 6.

FIG. 8 is a schematic illustration of a fourth embodiment of a PV cell having passivated front and backface contacts.

FIG. 9 is a flowchart of a process for fabricating the PV cell of FIG. 8.

### DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles of the disclosure as would normally occur to a person of ordinary skill in the art to which this disclosure pertains.

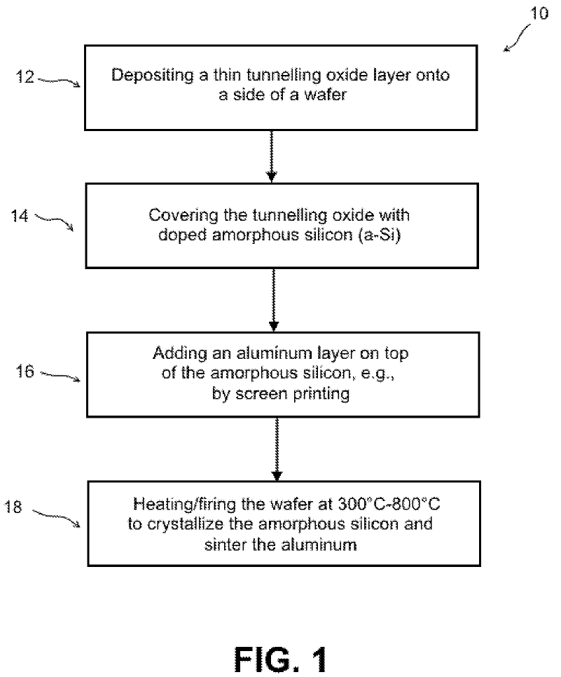

Referring to FIG. 1, the disclosure is directed to methods of forming passivated contacts for photovoltaic cells by incorporating the steps of depositing a tunneling oxide on at least one face of a wafer (block 10), covering the oxide with doped amorphous silicon (block 12) and then adding an aluminum layer on top of the amorphous silicon (block 14), (which is preferably screen printed aluminum although not necessarily). The wafer is then heated at 300°-800° C. to crystallize the amorphous silicon layer while simultaneously sintering the screen printed aluminum layer (block 16). These steps are performed generally in the order depicted in FIG. 1 although they need not be performed in sequence as other process steps may be included between these steps as needed. In addition, any of the steps in FIG. 1 may be performed in conjunction with other processing steps as may be known to a person of ordinary skill in the art.

According to the steps of FIG. 1, the aluminum layer is used as a catalyst for crystallization of the doped amorphous silicon layer (also referred to as aluminum induced crystallization (AIC)). These steps can be used to produce passivated contact structures on the backface as well as the front face of PV cells passivated contacts. The passivating the backface and/or front face contacts serves to reduce or suppress a recombination of the charge carriers generated at the backface and/or front face, respectively, and, as a result, improve efficiency of the cells.

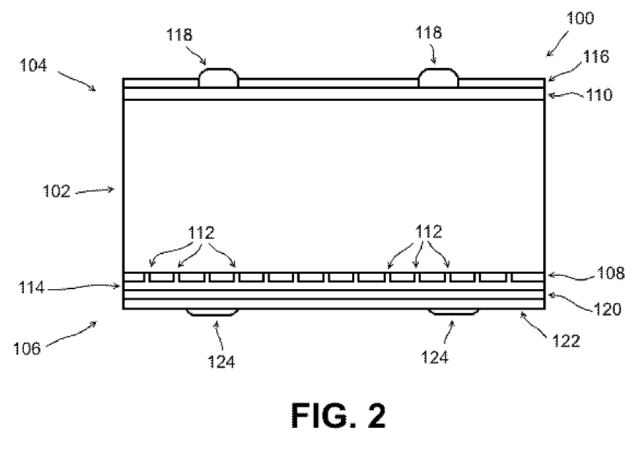

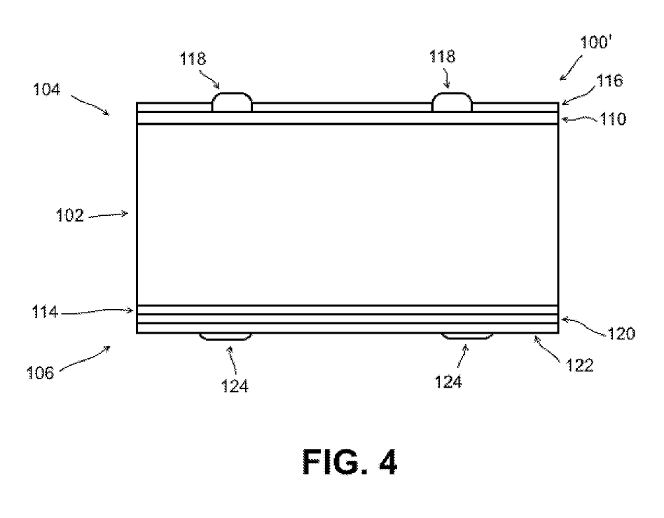

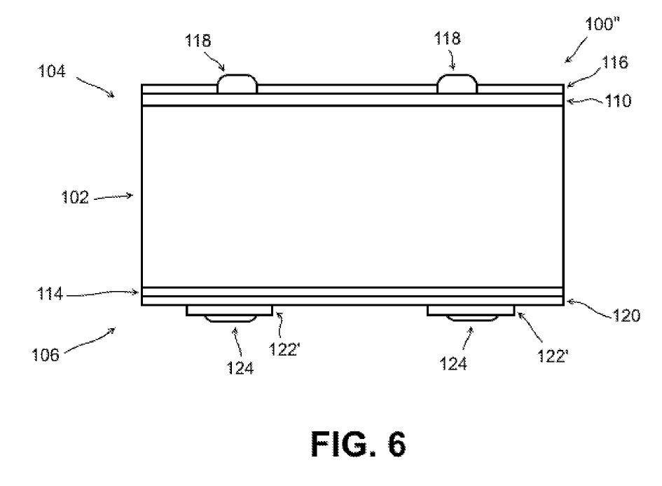

As discussed below, these steps can be incorporated into fabricating processes for photovoltaic cells to produce passivated emitter and rear contact (PERC) photovoltaic cells having full back surface fields in conventional PV cells, which have a full backface metallization (FIGS. 2 and 4), as well as PV cells having a partial backface metallization (FIG. 6), commonly referred to as bifacial cells. These steps can be incorporated into the fabricating processes for other types of PV cells to produced passivated backface contacts, such as for interdigitated back contact (IBC) PV cells, as well to produce passivated front face contacts for certain types of cells. It is also possible for these steps to be utilized to produce PV cells having both passivated backface and front face contacts.

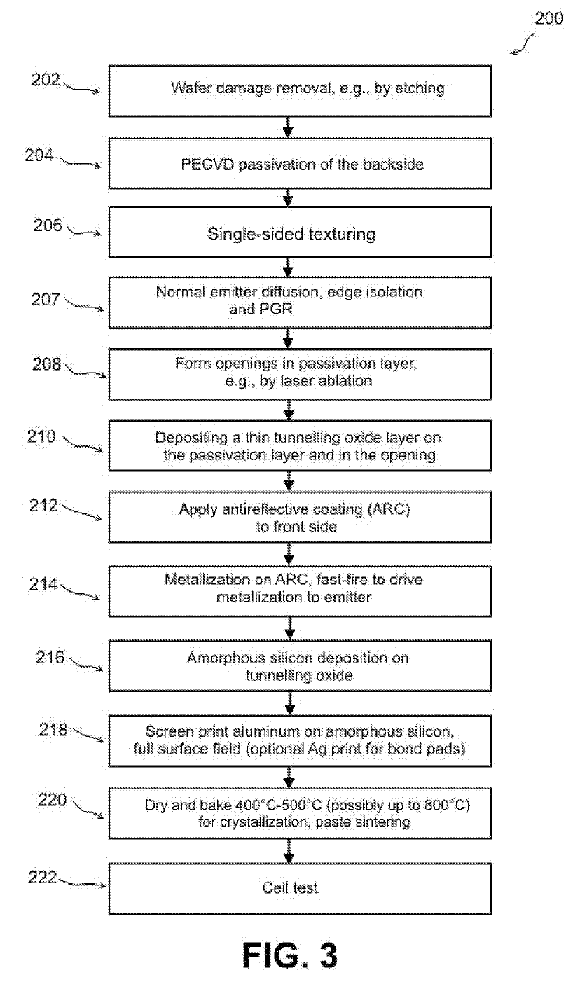

Referring to FIGS. 2 and 3, a first embodiment of a PERC PV cell and a method or process for fabricating the PERC PV cell based on the present disclosure are shown. The PERC cell 100 is depicted in FIG. 2, and the process sequence is depicted in FIG. 3. The process starts with a wafer 102, such as a silicon wafer, having a front face 104 and a backface 106. In this embodiment, the wafer 102 is p-doped although it is also possible, with appropriate modifications to the process steps, for the wafer to be n-doped.

Referring to FIG. 3, the wafer 102 is initially processed by removing damage from the wafer resulting from the steps of the wafer fabrication process, such as mounting and saw cutting, or dicing (block 202). The damage is removed typically by etching with an etching solution, such as Sodium hydroxide (NaOH) or Potassium hydroxide (KOH) and the like, to remove certain thicknesses of the wafer on each face which have been damaged. The wafer 102 may then be further cleaned and polished if desired.

After the damage removal, a passivation layer (108, FIG. 2) or layer stack is generated on the backface 106 of the wafer 102 (block 204). The passivation layer 108 may comprise, for example, a SiO₂/SiNₓ passivation layer or an Al₂O₃/SiNₓ passivation layer. The passivation layer 108 may be generated by plasma-enhanced chemical vapor deposition (PECVD) although any suitable processing method may be used, including other chemical vapor deposition (CVD) methods, atomic layer deposition (ALD), sputtering, and the like.

After the passivation layer 108 has been generated, a texturing process is performed to texture the front face of the wafer 104 (block 206). The front face is textured, e.g., by chemical etching, to produce a rough, or jagged, topology on the front face which result in angled surfaces on the front face that can deflect light into the solar cell rather than away from the surface of solar cell. The texturing improves efficiency by reducing optical losses due to reflection and increasing absorption trapping the light in the cell. In the embodiment of FIGS. 2 and 3, only the front face 104 is textured because, at this point, the backface 106 of the wafer is protected by the passivation layer 108 which serves as an etching barrier layer.

In a subsequent method step, a diffusion process is performed to introduce a doped layer 110 into the front face 104 of the wafer 102 (block 207). In the embodiment of FIG. 2, the doped layer 110 is configured to serve as an emitter layer. To produce the emitter layer 110, phosphorus is diffused into the wafer to produce an n-doped surface layer 7 on the p-substrate. The phosphorus diffusion may be performed, for example, by exposing the wafer to liquid or gaseous phosphorus oxychloride (POCl₃). Other processing steps, as are known in the art, may be performed at this stage, such as edge isolation, Phosphorous (Silicate) Glas Removal (PGR) and the like (block 207).

After the phosphorus diffusion (and PSG removal, edge isolation and any processing steps performed in the previous stage), a processing step is performed to create small openings 112 (FIG. 2) in the passivation layer 108 down to the silicon wafer (block 208) which will be used to form electrical connections to a backface conductor formed in a later step. In the embodiment of FIGS. 2 and 3, the openings 112 are formed using a laser ablation process. Laser ablation enables the passivation layer material to be in a strictly controlled and very targeted manner so that openings are formed having desired dimensions.

At this point, a thin tunneling oxide layer 114 is generated on the backface 106 of the wafer (block 210). This step corresponds to the first process step (12) from FIG. 1. The tunneling oxide 114 forms a layer that covers the passivation layer 108 and fills the openings 112 formed in the previous step. The oxide 114 may be generated in any suitable manner including, for example, nitric acid oxidation (e.g., a nitric acid dip), Ozone oxidation or thermal oxidation processes.

An anti-reflection coating (ARC) 116 (FIG. 2), such as silicon nitride or some other suitable material, may be provided on the front face 104 of the cell to further reduce reflection losses (block 212). The anti-reflection coating process in most cases is performed after the tunneling oxide has been generated on the backface of the wafer. However, the anti-reflection coating 116 may be introduced onto the front face of the wafer before the tunneling oxide 114 is generated, if desired or necessary.

After the thin oxide 114 has been generated on the backface 106 and the anti-reflection coating 116 has been provided on the front face 104, a process is carried out to form the front face contacts for the cell (block 214). In the embodiment of FIGS. 2 and 3, the front face contacts 118 are formed by screen printing a conductive paste, e.g., including aluminum and/or silver, onto the ARC 116 at desired locations to produce the contacts. After screen printing the front contacts 118, a firing step is performed in which the wafer is heated at a temperature that is sufficient to cause the screen printed material on the front face to be driven through the anti-reflection coating so as to make contact with the emitter layer (block 214).

An amorphous silicon layer 120 is then deposited on the backface of the wafer on top and covering the thin oxide layer (block 216). This step corresponds to the second step (14) depicted in FIG. 1. The amorphous silicon is preferably highly doped a-Si using, for example, boron as the dopant. In one embodiment, the a-Si layer has a doping concentration in a range from approximately 10¹⁸ atoms/cm³ to approximately 10²² atoms/cm³. Preferably, the a-Si layer has a doping concentration of approximately 10²⁰ atoms/cm³. The amorphous silicon is deposited by sputtering although other methods may be used, such as PECVD. In an alternative embodiment, the amorphous silicon may be combined with protocrystalline silicon (pc-Si). In this embodiment, the a-Si/pc-Si may be deposited, for example, as a paste.

After the amorphous silicon has been deposited, an aluminum layer 122 is screen printed on the backface on top of and covering the amorphous silicon layer 120 (block 218) (step 16 from FIG. 1). In addition to the screen printed aluminum 122, an additional screen printing may be performed (although not necessarily) to generate bond pads 124, or solder pads, on the aluminum layer 120. In the embodiment of FIGS. 2 and 3, the bond pads are formed by screen printing silver (Ag) onto the aluminum layer.

The wafer is then subjected to a heating process by exposing the wafer to a temperature that is suitable to cause aluminum induced crystallization (AIC) of the amorphous silicon layer using the screen printed aluminum as the catalyst while simultaneously sintering the screen printed aluminum (block 220). The temperature is in a range from approximately 400° C. to approximately 800° C. Preferably, the temperature is in a range from approximately 400° C. to approximately 500° C. Prior to the last heating step, a drying step may be performed to dry the screen printed paste by placing the wafer in a drier (block 220). Subsequent to the last heating step, cell testing may be performed to determine the performance of the cell (block 222). Other steps may be performed as needed prior to or after the last heating step. In the resulting PV cell, the doping of the amorphous silicon induces a strong full back surface field across the thin oxide to enable tunneling current conduction while maintaining good chemical passivation.

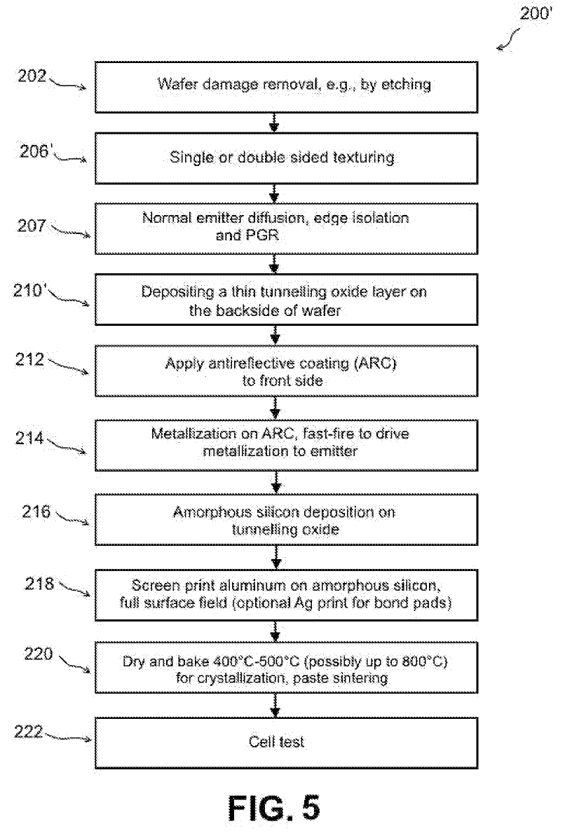

Referring now to FIGS. 4 and 5, a second embodiment of a PERC PV cell and a method or process for fabricating the PERC PV cell based on the present disclosure are shown. The PERC cell 100′ is depicted in FIG. 4, and the process sequence 200′ is depicted in FIG. 5. The cell 100′ and the process sequence 200′ correspond substantially to the cell 100 and process sequence of FIGS. 2 and 3, the main difference being the omission of the steps related to the PECVD passivation layer 108 (block 204) and the openings 112 (block 208).

In addition, in the process of FIG. 5, because the passivation layer has been omitted, single-sided or double-sided texturing may be performed (block 206′), and the tunneling oxide 114 is deposited directly on the wafer rather than a passivation layer (block 210′). The tunneling oxide 114 may be deposited using a single-sided deposition process or a double-sided deposition process followed by a removal step, e.g., by etching, to remove the oxide from the front face 104. With the process of FIG. 5, care must be taken to ensure that the aluminum from the screen printed aluminum layer reacts only on the amorphous silicon and not on the tunneling oxide layer. A reaction between the aluminum and the tunneling oxide could result in deterioration in the passivation provided by tunneling oxide which is the only passivation layer provided in this embodiment. An advantage of the process of FIG. 5 is that it does not increase the use of CVD equipment relative to processes that are used in state of the art solar cell manufacturing processes.

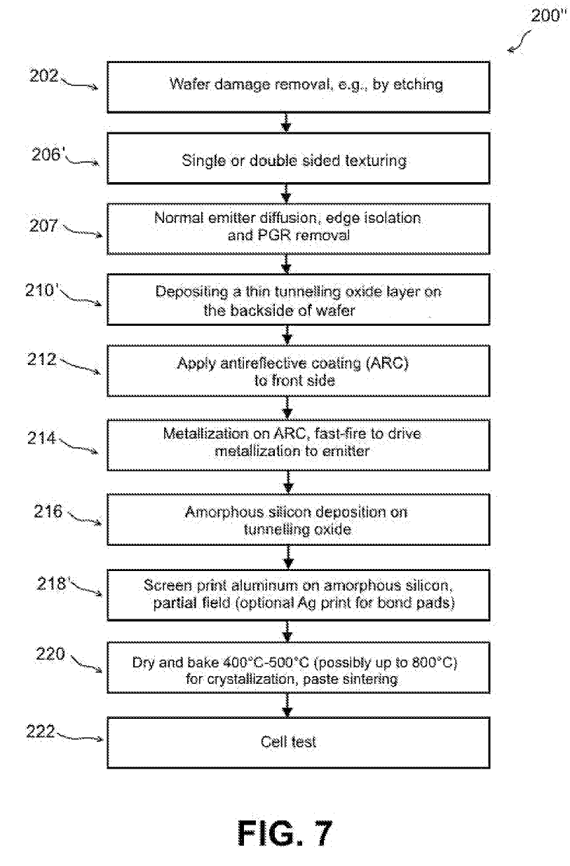

FIGS. 6 and 7 are directed to a third embodiment of PERC cell 100″ (FIG. 6) and a process 200″ sequence for fabricating the PERC cell (FIG. 7). In this embodiment, the PERC cell comprises a bifacial cell. As is known in the art, a bifacial cell includes a partial backface metallization 122′ (FIG. 6) in order to allow areas (not having metallization) that can admit light into the cell. A bifacial cell therefore can receive light via both the front and back face 104, 106 of the cell. In the embodiments of FIGS. 6 and 7, the backface PECVD passivation 108 (block 204) and openings 112 (block 208) have also been omitted. In addition, in the process of FIG. 5, because the passivation layer has been omitted, single-sided or double-sided texturing may be performed (block 206′), and the tunneling oxide 114 is deposited directly on the wafer rather than a passivation layer (block 210′). The tunneling oxide 114 may be deposited using a single-sided deposition process or a double-sided deposition process followed by a removal step, e.g., by etching, to remove the oxide from the front face 104. To form a bifacial device, the aluminum layer 122″ is screen printed on partial field on the amorphous silicon layer 120 (block 218′). Although not visible in FIG. 6, the partial metallization 122′ may form a grid pattern on the backface 106 of the wafer.

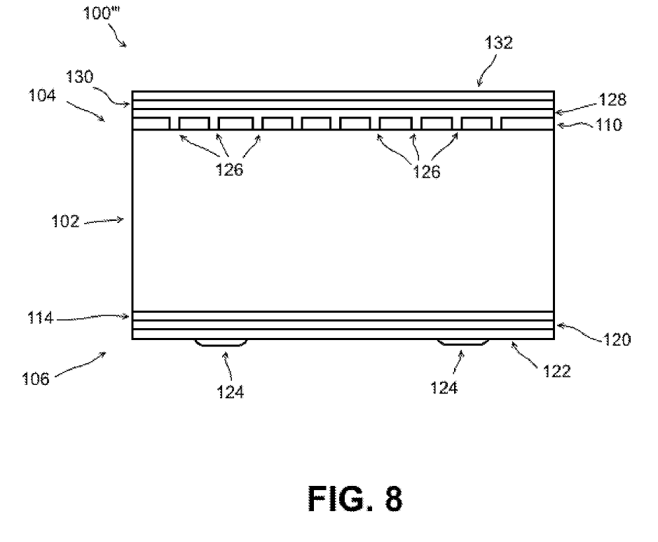

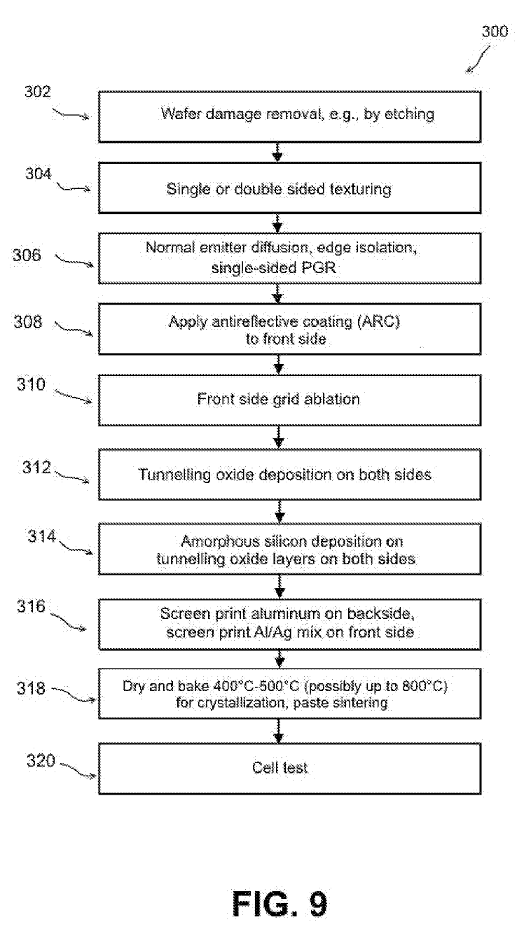

FIGS. 8 and 9 are directed to a fourth embodiment of PV cell 100″' (FIG. 8) and a process sequence 300 for fabricating the PV cell (FIG. 9). In the embodiment of FIGS. 8 and 9, the method steps from FIG. 1 are used to form passivated contact structures on both the front and back faces of a wafer. Similar to the previous embodiments, damage removal etching may be performed to remove damage from the wafer resulting from wafer handling (block 302). There is no backface PECVD passivation. Therefore, single- or double-sided texturing may be performed (block 304). In this embodiment, emitter diffusion, edge isolation and single-sided PGR (block 306) are performed after texturing, the anti-reflection coating is applied (block 308). Openings 126 are formed in the emitter layer 110, such as for a grid-shaped contact structure, in the emitter layer 110, e.g., by laser ablation (block 310). Tunneling oxides 114, 128 are deposited on both faces of the wafer (block 312), and amorphous silicon 112, 130 is deposited, e.g., by sputtering, on the tunneling oxide layers on both faces (block 314). To form the front face contacts, an aluminum-silver (Al/Ag) mix 132 is printed onto the front face 104 (block 316). Aluminum 122 is screen printed on the backface for the backface contacts in full or partial field (block 316). The wafer is then dried and baked at a temperature in the range of approximately 400° C. to approximately 800° C., and, preferably, in a range from approximately 400° C. to approximately 500° C., to crystallize the amorphous silicon and sinter the aluminum as described above (block 318).

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected.

1. A method of fabricating a passivated contact for a photovoltaic cell, comprising:
depositing a tunneling oxide layer on a first face of a substrate;
depositing a doped amorphous silicon layer on top of the tunneling oxide layer;
screen printing an aluminum layer on top of the doped amorphous silicon layer, the aluminum layer being configured to serve as a crystallization catalyst for the doped amorphous silicon layer; and
heating the amorphous silicon layer and the aluminum layer to a crystallization temperature, the crystallization temperature being configured to cause the doped amorphous silicon to crystallize and to sinter the aluminum layer.

2. The method of claim 1, wherein the crystallization temperature is in a range from approximately 400° C. to approximately 800° C.

3. The method of claim 2, wherein the crystallization temperature is in a range from approximately 400° C. to approximately 500° C.

4. The method of claim 1, further comprising:
forming an anti-reflection coating layer on a second face of the substrate.

5. The method of claim 1, further comprising:
texturing at least one of the first face and a second face of the substrate prior to depositing the tunneling oxide, the second face being opposite from the first face; and
performing a diffusion process to form a base region in the substrate of a first conductivity type prior to depositing the tunneling oxide.

6. The method of claim 1, further comprising:
forming electrical contacts on a second face of the substrate.

7. The method of claim 6, wherein the electrical contacts are formed by screen printing a metallization and heating the metallization to form the electrical contacts.

8. A method of fabricating a passivated full-field back contact for a photovoltaic cell, comprising:
depositing a tunneling oxide layer on a back face of a substrate;
depositing a doped amorphous silicon layer on top of the tunneling oxide layer;
screen printing an aluminum layer on top of the amorphous silicon layer on a full field to form a full-field back contact, the aluminum layer being configured to serve as a crystallization catalyst for the amorphous silicon layer; and
heating the amorphous silicon layer and the aluminum layer to a crystallization temperature, the crystallization temperature being configured to cause the amorphous silicon to crystallize and to sinter the aluminum layer to form a full-field back contact.

9. The method of claim 8, wherein the first temperature is in a range from approximately 400° C. to approximately 800° C.

10. The method of claim 8, further comprising:
forming electrical contacts on a front face of the substrate.

11. The method of claim 8, further comprising:
forming an anti-reflection coating layer on a front face of the substrate.

12. The method of claim 8, further comprising:
forming a passivating layer on the front face of the substrate prior to depositing the tunneling oxide layer;
removing portions of the passivating layer to form openings in the passivating layer that expose the first face of the substrate; and
depositing the tunneling oxide layer on the passivation layer and on the first face of the substrate through the openings.

13. A method of fabricating a passivated partial-field back contact for a photovoltaic cell, comprising:
depositing a tunneling oxide layer on a back face of a substrate;
depositing a doped amorphous silicon layer on top of the tunneling oxide layer;
screen printing an aluminum layer on top of the amorphous silicon layer on a partial field to form a partial-field back contact, the aluminum layer being configured to serve as a crystallization catalyst for the amorphous silicon layer; and
heating the amorphous silicon layer and the aluminum layer to a crystallization temperature, the crystallization temperature being configured to cause the amorphous silicon to crystallize and to sinter the aluminum layer to form a partial-field back contact.

14. The method of claim 13, wherein the aluminum layer is screen printed to form a grid pattern on the amorphous silicon layer.

15. The method of claim 13, wherein the crystallization temperature is in a range from approximately 400° C. to approximately 800° C.

16. The method of claim 13, further comprising:
forming electrical contacts on a front face of the substrate.

17. The method of claim 13, further comprising:
forming an anti-reflection coating layer on a front face of the substrate.

18. A method of fabricating passivated front and back contacts for a photovoltaic cell, comprising:
depositing a tunneling oxide layer on a back face of a substrate;
depositing a doped amorphous silicon layer on top of the tunneling oxide layer;
screen printing an aluminum layer on top of the amorphous silicon layer on a partial field to form a partial-field back contact, the aluminum layer being configured to serve as a crystallization catalyst for the amorphous silicon layer;
screen printing an aluminum-silver mix layer on the front face of the substrate; and
heating the substrate to a crystallization temperature, the crystallization temperature being configured to cause the amorphous silicon to crystallize and to sinter the aluminum layer and the aluminum-silver layer to form back and front contacts, respectively, for the photovoltaic cell.

19. The method of claim 18, wherein the crystallization temperature is in a range from approximately 400° C. to approximately 800° C.

20. The method of claim 18, further comprising:
forming an anti-reflection coating layer on the front face of the substrate; and
using layers to open vias through the anti-reflection coating.
